(19) United States
(12) Patent Application Publication
(10) Pub. No.: US 2025/0260382 A1
(43) Pub. Date: Aug. 14, 2025

(54) BULK ACOUSTIC WAVE DEVICE INCLUDING DIELECTRIC LAYER FOR FRAME MODE SUPPRESSION

(71) Applicant: Skyworks Global Pte. Ltd., Singapore (SG)

(72) Inventors: Zongliang Cao, Irvine, CA (US); Yanbo He, Irvine, CA (US); Kwang Jae Shin, Yongin-si (KR)

(21) Appl. No.: 19/040,762

(22) Filed: Jan. 29, 2025

Related U.S. Application Data
(60) Provisional application No. 63/551,382, filed on Feb. 8, 2024.

(51) Int. Cl. H03H 9/02; H03H 3/04; H03H 9/13; H03H 9/17; H03H 9/56

(52) U.S. Cl. CPC H03H 9/02086; H03H 3/04; H03H 9/132; H03H 9/173; H03H 9/568; H03H 2003/0478

(57) ABSTRACT

Aspects of this disclosure relate to a bulk acoustic wave device having a main acoustically active region and a frame region. The bulk acoustic wave device can include a first electrode, a second electrode spaced apart from the first electrode in a first direction, a frame structure in the frame region, a piezoelectric layer positioned between the first electrode and the second electrode in at least the main acoustically active region, and a dielectric layer in at least part of the frame region such that the piezoelectric layer is positioned between portions of the dielectric layer in a second direction different from the first direction. The dielectric layer can include a different material than the piezoelectric layer.

### CROSS REFERENCE TO PRIORITY APPLICATION

Any and all applications for which a foreign or domestic priority claim is identified in the Application Data Sheet as filed with the present application are hereby incorporated by reference under 37 C.F.R. § 1.57. This application claims the benefit of priority of U.S. Provisional Application No. 63/551,382, filed Feb. 8, 2024 and titled “BULK ACOUSTIC WAVE DEVICE INCLUDING DIELECTRIC LAYER FOR FRAME MODE SUPPRESSION,” the disclosure of which is hereby incorporated by reference in its entirety and for all purposes.

### BACKGROUND

### Technical Field

The disclosed technology relates to acoustic wave devices. Embodiments of this disclosure relate to bulk acoustic wave devices with a piezoelectric layer positioned at least partially between portions of a dielectric layer.

### Description of Related Technology

Acoustic wave filters can be implemented in radio frequency electronic systems. For instance, filters in a radio frequency front end of a mobile phone can include acoustic wave filters. An acoustic wave filter can be a band pass filter. A plurality of acoustic wave filters can be arranged as a multiplexer. For example, two acoustic wave filters can be arranged as a duplexer.

An acoustic wave filter can include a plurality of acoustic wave resonators arranged to filter a radio frequency signal. Example acoustic wave resonators include surface acoustic wave (SAW) resonators and bulk acoustic wave (BAW) resonators. In BAW resonators, acoustic waves propagate in the bulk of a piezoelectric layer. Example BAW resonators include film bulk acoustic wave resonators (FBARs) and BAW solidly mounted resonators (SMRs).

For BAW devices, achieving a high quality factor (Q) is generally desirable. Suppressing and/or attenuating spurious mode(s) in BAW devices is also generally desirable. There are technical challenges related to increasing Q and further suppressing spurious mode(s) while meeting other performance specifications for BAW devices.

### SUMMARY OF CERTAIN INVENTIVE ASPECTS

The innovations described in the claims each have several aspects, no single one of which is solely responsible for its desirable attributes. Without limiting the scope of the claims, some prominent features of this disclosure will now be briefly described.

One aspect of this disclosure is a bulk acoustic wave device having a main acoustically active region and a frame region. The bulk acoustic wave device includes a first electrode, a second electrode spaced apart from the first electrode in a first direction, a frame structure in the frame region, a piezoelectric layer positioned between the first electrode and the second electrode in at least the main acoustically active region, and a dielectric layer in at least part of the frame region such that the piezoelectric layer is positioned between portions of the dielectric layer in a second direction different from the first direction. The dielectric layer includes a different material than the piezoelectric layer.

The frame region can surround the main acoustically active region.

The dielectric layer can span the frame region. The dielectric layer can be included in an intermediate region of the bulk acoustic wave device that is between the frame region and the main acoustically active region. The dielectric layer can be included in an outer region of the bulk acoustic wave device that is on an opposite side of the frame region than the main acoustically active region.

The bulk acoustic wave device can include an air cavity. The dielectric layer can be positioned over the air cavity in the at least part of the frame region.

The dielectric layer can include an oxide. The dielectric layer can include a nitride. The dielectric layer can include a carbide. The dielectric layer can include at least one of silicon oxide, silicon nitride, silicon carbide, gallium oxide, or gallium nitride.

The dielectric layer includes a material that has an acoustic impedance with a magnitude that is greater than a magnitude of an acoustic impedance of the piezoelectric layer. The magnitude of the acoustic impedance of the material can be at least 10% greater than the magnitude of the acoustic impedance of the piezoelectric layer. The dielectric layer can include a material that has an acoustic impedance with a magnitude that is less than a magnitude of an acoustic impedance of the piezoelectric layer.

The dielectric layer can have a higher thermal conductivity than the piezoelectric layer.

A piezoelectric coupling coefficient (e33) of the dielectric layer can have a magnitude that is no more than 50% of a magnitude of an e33 of the piezoelectric layer. A piezoelectric coupling coefficient (e33) of the dielectric layer can have a magnitude that is no more than 20% of a magnitude of an e33 of the piezoelectric layer.

The frame structure can include a raised frame structure and a recessed frame structure.

The frame region can include a first raised frame region and a second raised frame region. The frame structure can include an additional raised frame layer in the second raised frame region relative to in the first raised frame region.

The frame structure can include a recessed frame structure.

Another aspect of this disclosure is a bulk acoustic wave device having a main acoustically active region and a frame region. The bulk acoustic wave device includes a first electrode, a second electrode spaced apart from the first electrode in a first direction; a frame structure positioned within the frame region, the frame structure surrounding the main acoustically active region; a piezoelectric layer positioned between the first electrode and the second electrode in at least the main acoustically active region; and a dielectric layer at least in the frame region such that the piezoelectric layer is positioned between portions of the dielectric layer in a second direction different from the first direction, the piezoelectric layer having a greater magnitude piezoelectric coefficient than the dielectric layer.

Another aspect of this disclosure is a bulk acoustic wave device having an active region and a frame region. The bulk acoustic wave device includes an acoustic reflector; a pair of electrodes including a first electrode and a second electrode; a piezoelectric layer positioned over the acoustic reflector and between the first electrode and the second electrode in the active region; a dielectric layer positioned over the acoustic reflector and laterally from the piezoelectric layer; and a frame structure positioned vertically relative to the dielectric layer.

Another aspect of this disclosure is a bulk acoustic wave device having an active region. The bulk acoustic wave device includes an acoustic reflector; a first electrode; a second electrode; a piezoelectric layer positioned over the acoustic reflector and between the first electrode and the second electrode in the active region; and a dielectric layer positioned over the acoustic reflector outside of the active region, the dielectric layer positioned laterally from the piezoelectric layer, and the dielectric layer being of a different material than the piezoelectric layer.

Another aspect of this disclosure is an acoustic wave filter for filtering a radio frequency signal. The acoustic wave filter includes a bulk acoustic wave device in accordance with any suitable principles and advantages disclosed herein and a plurality of additional acoustic wave resonators. The bulk acoustic wave device and the plurality of additional acoustic wave resonators are configured to filter the radio frequency signal.

Another aspect of this disclosure is a multiplexer for filtering radio frequency signals. The multiplexer includes a first filter including a bulk acoustic wave device in accordance with any suitable principles and advantages disclosed herein, and a second filter coupled to the first filter at a common node.

Another aspect of this disclosure is a radio frequency module that includes a filter including a bulk acoustic wave device in accordance with any suitable principles and advantages disclosed herein, radio frequency circuitry, and a package structure enclosing the filter and the radio frequency circuitry.

Another aspect of this disclosure is a radio frequency system that includes an antenna, a filter including a bulk acoustic wave device in accordance with any suitable principles and advantages disclosed herein, and an antenna switch configured to selectively electrically connect the antenna and a signal path that includes the filter.

Another aspect of this disclosure is a wireless communication device that includes a radio frequency front end including a filter that includes a bulk acoustic wave device in accordance with any suitable principles and advantages disclosed herein, an antenna coupled to the radio frequency front end, a transceiver in communication with the radio frequency front end, and a baseband system in communication with the transceiver.

Another aspect of this disclosure is a method of radio frequency signal processing. The method includes receiving a radio frequency signal via at least an antenna; and filtering the radio frequency signal with a filter that includes a bulk acoustic wave device in accordance with any suitable principles and advantages disclosed herein.

### BRIEF DESCRIPTION OF THE DRAWINGS

Embodiments of this disclosure will now be described, by way of non-limiting example, with reference to the accompanying drawings.

FIG. 1A is a cross-sectional diagram of a bulk acoustic wave (BAW) device including a piezoelectric layer positioned at least partially between portions of a dielectric layer according to an embodiment. FIG. 1B is an example plan view of the BAW device of FIG. 1A. FIG. 1C is another example plan view of the BAW device of FIG. 1A.

FIG. 2A is a cross-sectional diagram of a BAW device including a piezoelectric layer positioned at least partially between portions of a dielectric layer according to an embodiment. FIG. 2B is a cross-sectional diagram of a BAW device including a piezoelectric layer positioned at least partially between portions of a dielectric layer according to another embodiment. FIG. 2C is a schematic cross-sectional side view of a portion of a BAW device including a temperature compensation layer according to an embodiment.

FIG. 3 is a cross-sectional diagram of a BAW device including an air cavity etched into a substrate and a piezoelectric layer positioned at least partially between portions of a dielectric layer according to an embodiment.

FIG. 4 is a cross-sectional diagram of a BAW device including a solid acoustic mirror and a piezoelectric layer positioned at least partially between portions of a dielectric layer according to an embodiment.

FIG. 5 is a cross-sectional diagram of a BAW device including a dual solid acoustic mirror and a piezoelectric layer positioned at least partially between portions of a dielectric layer according to an embodiment.

FIG. 6A is a cross-sectional diagram of a BAW device including a plurality of raised frame layers and a piezoelectric layer positioned at least partially between portions of a dielectric layer according to an embodiment. FIG. 6B is a zoomed in view of a metal top electrode connection area of the BAW device of FIG. 6A that includes the frame region. FIG. 6C is a zoomed in view of the frame region near a metal bottom electrode connection area of the BAW device of FIG. 6A.

FIG. 7 is a cross-sectional diagram of a BAW device including a suspended frame region and a piezoelectric layer positioned at least partially between portions of a dielectric layer according to an embodiment.

FIG. 8 is a cross-sectional diagram of a portion of a BAW device including a piezoelectric layer positioned at least partially between portions of a dielectric layer and a raised frame layer below the piezoelectric layer according to an embodiment.

FIG. 9 is a cross-sectional diagram of a portion of a BAW device including a piezoelectric layer positioned at least partially between portions of a dielectric layer and raised frame layers below the piezoelectric layer according to an embodiment.

FIG. 10 a cross-sectional diagram of a portion of a BAW device including a piezoelectric layer positioned at least partially between portions of a dielectric layer that extends beyond a frame region toward the main acoustically active region according to an embodiment.

FIG. 11 is a flow diagram of a method of manufacturing a BAW device with a piezoelectric layer positioned at least partially between portions of a dielectric layer according to an embodiment.

FIG. 12A is a schematic diagram of a ladder filter that includes one or more BAW resonators according to an embodiment.

FIG. 12B is schematic diagram of a band pass filter.

FIGS. 13A, 13B, 13C, and 13D are schematic diagrams of multiplexers that include a filter with one or more BAW resonators according to an embodiment.

FIGS. 14, 15, and 16 are schematic block diagrams of modules that include a filter with one or more BAW resonators according to an embodiment.

FIG. 17 is a schematic block diagram of a wireless communication device that includes a filter with one or more BAW resonators according to an embodiment.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings. Any suitable principles and advantages of the embodiments disclosed herein can be implemented together with each other. The headings provided herein are for convenience only and are not intended to affect the meaning or scope of the claims.

Increasing the quality factor (Q) of a given bulk acoustic wave (BAW) resonator can effectively reduce energy losses. Such energy losses can include, for example, insertion losses within a filter or phase noise in an oscillator. BAW resonator performance can be enhanced and/or optimized by one or more of area, geometry, frame structure, or the like. BAW devices disclosed herein can achieve improved performance by including a dielectric layer such that a piezoelectric layer in a main acoustically active region of a BAW device is positioned between portions of the dielectric layer.

BAW devices can include frame structures. A frame structure is a structure that adjusts mass loading in a portion of a BAW device over an acoustic reflector. A frame structure can include a raised frame structure that adds mass loading and/or a recessed frame structure that reduces mass loading. A raised frame structure can include an additional layer and/or a thicker portion of material that increases mass loading in a portion of a BAW device relative to a main acoustically active region. In some applications, a raised frame layer can include a different material than layers in contact with the raised frame layer. In some applications, a raised frame layer can include a same material as a layer in contact with the raised frame layer. A raised frame structure can be a multi-layer structure that includes two or more raised frame layers. A recessed frame structure can include a thinner portion of a layer of a BAW device that decreases mass loading in a portion of the BAW device relative to a main acoustically active region. Certain BAW devices include a frame structure around the main acoustically active region of the BAW device. Such a frame structure can be included around a periphery of the BAW device. In certain applications, the frame structure can surround the main acoustically active region in plan view. In some other applications, the frame structure can be around some but not all of the main acoustically active region in plan view.

A BAW device can include a first electrode, a second electrode, and a piezoelectric layer positioned between the first and second electrodes. A frame structure, such as a raised frame and/or a recessed frame, can be positioned around a main acoustically active region of the BAW device to reduce lateral energy leakage from the main acoustically active region. A region of the BAW device that includes the frame structure can be referred to as a frame region. A raised frame structure can create a resonance at a frequency that is below a resonant frequency of the main acoustically active region of the BAW device. This resonance can be below a main resonant frequency of the BAW device. A resonance associated with the raised frame structure can be referred to as a raised frame mode. The raised frame mode can be undesirable in certain applications.

This disclosure provides technical solutions that can suppress and/or eliminate raised frame modes. At the same time, technical solutions disclosed herein can maintain a desired electromechanical coupling coefficient (kt²) and significantly increase a quality factor (Q) of a BAW device. BAW devices disclosed herein include a dielectric layer that vertically overlaps with a frame structure that can suppress a frame mode of the frame structure. These BAW devices can be referred to as having a passive frame. BAW devices disclosed herein can achieve significant performance improvements over other BAW devices. Filters that include BAW devices disclosed herein can provide improved performance in a variety of applications, such as but not limited to fifth generation (5G) New Radio (NR) applications. BAW devices disclosed herein can improve performance in applications where a plurality of filters are connected together with each other.

Aspects of this disclosure relate to a BAW device that includes a piezoelectric layer positioned laterally between portions of a dielectric layer. The dielectric layer can have a lower magnitude piezoelectric coefficient than the piezoelectric layer. The piezoelectric coefficient can be a piezoelectric coupling coefficient (e₃₃), for example. The portions of the dielectric layer can be in a peripheral region of the BAW device that is around the piezoelectric layer in the main acoustically active region of the BAW device. The dielectric layer can surround the piezoelectric layer in the BAW device. The BAW device can include a frame structure in the peripheral region. The frame structure can vertically overlap with the dielectric layer. The frame structure can include one or more raised frame structures and/or one or more recessed frame structures. The peripheral region can extend beyond the frame structure toward the main acoustically active region. Alternatively or additionally, the peripheral region can extend away from the main acoustically active region. By including a dielectric layer, which is less piezoelectric than the piezoelectric layer, in the peripheral region of the BAW device, there can be little or no resonance associated with the frame structure.

Aspects of this disclosure relate to manufacturing BAW devices that include a piezoelectric layer positioned laterally between portions of a dielectric layer. The dielectric layer can be positioned between a first electrode and a second electrode of a BAW device over an acoustic reflector. In certain applications, the dielectric layer can extend beyond the first electrode and/or the second electrode away from the piezoelectric layer. The dielectric layer includes a different material than the piezoelectric layer. The dielectric layer can be less piezoelectric than the piezoelectric layer such that there is little or no acoustic energy created by the dielectric layer. The dielectric layer can be positioned vertically relative to a frame structure, such as a raised frame structure, of the BAW device. With the dielectric layer positioned vertically relative to the frame structure, the BAW device should not generate a significant frame mode.

The dielectric layer disclosed herein can have a piezoelectric coupling coefficient (e₃₃) with a magnitude that is in a range from 0% to less than 50% of the magnitude of the piezoelectric coupling coefficient of the piezoelectric layer in the main acoustically active region. In certain embodiments, a magnitude of the e₃₃ of the dielectric layer is 20% or less of a magnitude of the e₃₃ of the piezoelectric layer. The lower magnitude of the piezoelectric coupling coefficient for the dielectric layer can increase Q of the BAW device and/or attenuate one or more spurs, such a spur associated with one or more frame modes.

BAW devices disclosed herein can significantly attenuate one or more spurious modes and increase Q, while maintaining an electromechanical coupling coefficient (kt²) at a relatively stable level. This can effectively decouple Q, kt², and strength of spurious modes in BAW devices.

### BAW Devices With Dielectric Layer for Frame Mode Suppression

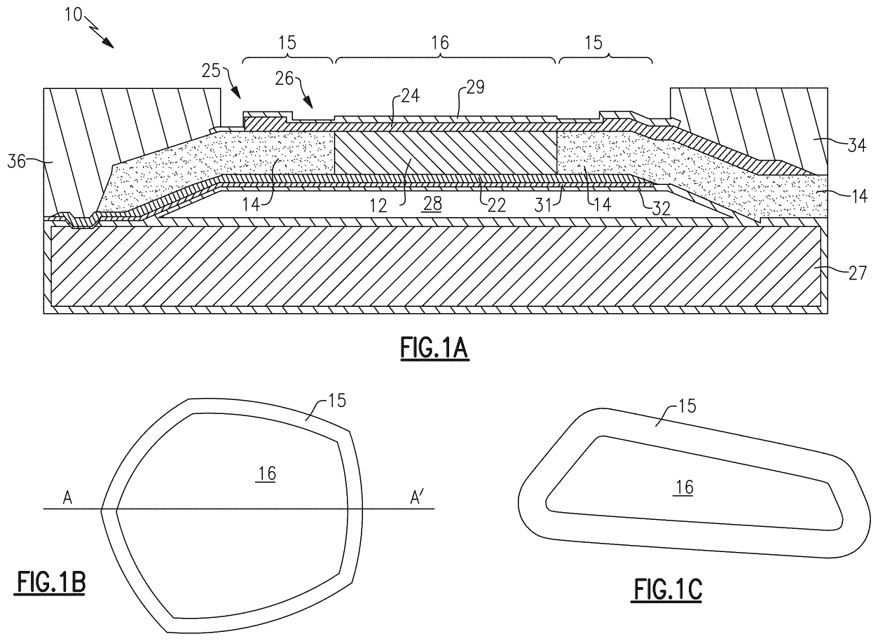

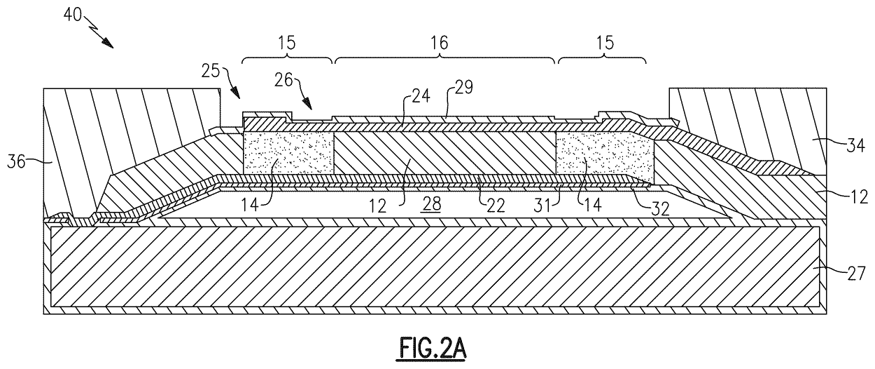

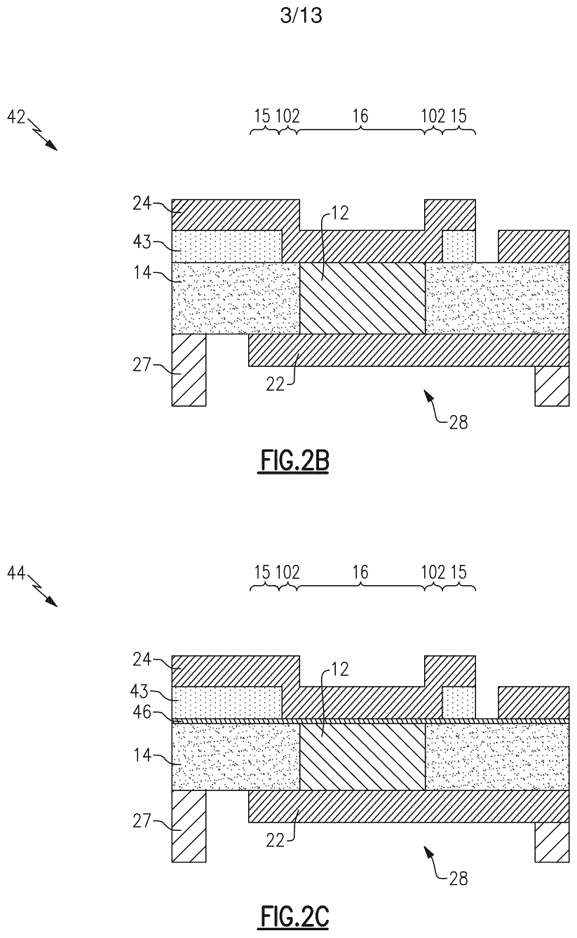

A BAW device can include a piezoelectric layer and a dielectric layer. The piezoelectric layer can be positioned laterally between portions of the dielectric layer. The portions of the dielectric layer can be in a peripheral region of the BAW device. Examples of such a BAW device will be discussed with reference to FIGS. 1A to 2B. Any suitable principles and advantages of these BAW devices can be implemented together with each other and/or with any suitable principles and advantages of other embodiments disclosed herein. BAW devices disclosed herein can be BAW resonators.

FIG. 1A is a cross-sectional diagram of a BAW device 10 including a piezoelectric layer 12 and a dielectric layer 14 according to an embodiment. In the BAW device 10, the dielectric layer 14 is in a frame region 15 of the BAW device 10. The piezoelectric layer 12 is included in a main acoustically active region 16 of the BAW device 10. In the BAW device 10, a peripheral region includes the frame region 15. The region of the BAW device 10 where the dielectric layer 14 is present can be referred to as a passive region. This region be referred to as a less piezoelectric region. This region can be referred to as a non-piezoelectric region. The frame region 15 surrounds the main acoustically active region 16 in plan view in the BAW device 10.

As illustrated, the BAW device 10 includes the piezoelectric layer 12, a first electrode 22, a second electrode 24, a raised frame structure 25, a recessed raised frame structure 26, a support substrate 27, an acoustic reflector such as an air cavity 28, and a passivation layer 29. The BAW device 10 also includes a seed layer 31 positioned between the first electrode 22 and passivation layer 32. One or more features of the BAW device 10 may be omitted in some embodiments.

The dielectric layer 14 can cause the BAW device 10 to exhibit no bulk piezoelectric effect or a weak bulk piezoelectric effect in the frame region 15 of the BAW device 10. This can advantageously avoid and/or suppress a frame mode. The dielectric layer 14 can include any suitable dielectric material. For example, the dielectric layer 14 can include silicon-based dielectric material, such as silicon oxide (e.g., silicon dioxide (SiO₂)), silicon nitride, or silicon carbide, or a gallium-based dielectric material, such as gallium oxide or gallium nitride. The dielectric layer 14 can include any suitable oxide, nitride, or carbide. In some embodiments, it can be beneficial to implement a dielectric material for the dielectric layer 14 so as to have a relatively large acoustic impedance mismatch between the dielectric layer 14 and the piezoelectric layer 12, as such a property can provide low dielectric and acoustic losses which may reduce and/or minimize the Q degradation as compared to implementing a dielectric material for the dielectric layer 14 that has a similar acoustic impedance as the piezoelectric layer 12. For example, the dielectric layer 14 can include a material that has an acoustic impedance similar to air (e.g., 428 rayl (Ry) at 0° C.) up to an acoustic impedance similar to the piezoelectric layer 12. As another example, the dielectric layer 14 can include a dielectric material that has larger acoustic impedance than the piezoelectric layer 12. In some embodiments, a difference between the acoustic impedance of the dielectric layer 12 and the acoustic impedance of the piezoelectric layer 12 can be more than 10%, more than 20%, or more than 30%. These acoustic impedance differences can be differences in magnitude. The dielectric layer 14 can have a thermal conductivity that is higher than a thermal conductivity of the piezoelectric layer 12. In some embodiments, a seed layer (not shown) can be provided over the first electrode 22 in the frame region 15 to facilitate deposition of the dielectric layer 14.

Although embodiments disclosed herein may be discussed with reference to BAW devices that include a dielectric layer, any suitable principles and advantages disclosed herein can be applied to BAW devices that include any suitable layer that is less acoustically active compared to the piezoelectric layer in place of the dielectric layer. The layer can be formed of different material than the piezoelectric layer of the BAW device. The layer can be referred to a less piezoelectric layer. The layer can be referred to a non-piezoelectric layer. The layer can be electrically insulating. Such a layer can be referred to an insulating layer, an insulator layer, or an electrically non-conductive layer.

Referring to FIG. 1A, the piezoelectric layer 12 and the dielectric layer 14 are respectively positioned in the frame region 15 and in the main acoustically active region 16 and have different properties in the BAW device 10. The dielectric layer 14 can be less piezoelectric than the piezoelectric layer 12. The dielectric layer 14 is positioned in the frame region 15 such that the piezoelectric layer 12 in the main acoustically active region 16 has a greater magnitude piezoelectric coefficient than the dielectric layer 14 in the frame region 15. The piezoelectric coefficient can be a piezoelectric coupling coefficient (e₃₃). In certain applications, the magnitude of e₃₃ of the dielectric layer 14 can be no more than 50% of the magnitude of e₃₃ of the piezoelectric layer 12. In some applications, the magnitude of e₃₃ of the dielectric layer 14 can be no more than 20% of the magnitude of e₃₃ of the piezoelectric layer 12. In some applications, the magnitude of e₃₃ of the dielectric layer 14 can be zero or close to zero. The dielectric layer 14 can also have a lower electromechanical coupling coefficient (kt²) than the piezoelectric layer 12. The dielectric layer 14 can extend beyond the frame region 15 away from the main acoustically active region 16 of the BAW device 10. As illustrated, the dielectric layer 14 extends beyond the frame region 15 away from the main acoustically active region 16 on opposing sides of the BAW device 10. In some other embodiments, the dielectric layer 14 can extend beyond a frame region on one side of a BAW device. The dielectric layer 14 can extend beyond where the first electrode 22 overlaps with the second electrode 24.

In some applications, the piezoelectric layer 12 can be formed in the pattern as shown in FIG. 1A and the dielectric layer 14 can be formed in areas where the piezoelectric layer 12 is not formed. In certain applications, at least a portion of a blanket piezoelectric layer can be removed to define the piezoelectric layer 12. The removed portion can be at least partially filled with a dielectric material. The filled dielectric material can define the dielectric layer 14. In some embodiments, the dielectric material can be overfilled and an excess portion of the dielectric material can be removed to form the dielectric layer 14.

BAW device 10 includes frame structure including raised frame structure 25 and recessed frame structure 26. The dielectric layer 14 overlaps with the raised frame structure 25 and the recessed frame structure 26 in the BAW device 10. The reduced or lack of a bulk piezoelectric effect in the dielectric layer 14 as compared to the piezoelectric layer 12 can suppress and/or eliminate a frame mode (e.g., a raised frame mode associated with the raised frame structure and/or a recessed frame mode associated with the recessed frame structure 26) in the BAW device 10.

The piezoelectric layer 12 can include a suitable material such as, but not limited to, aluminum nitride (AlN), zinc oxide (ZnO), or lead zirconium titanate (PZT). In certain applications, the piezoelectric layer 12 can include AlN. The piezoelectric material can be doped or undoped. For example, an AlN-based piezoelectric layer can be doped with any suitable dopant, such as scandium (Sc), chromium (Cr), magnesium (Mg), sulfur(S), yttrium (Y), silicon (Si), germanium (Ge), oxygen (O), hafnium (Hf), zirconium (Zr), titanium (Ti), calcium (Ca), boron (B), carbon (C), europium (Eu), or the like. In certain applications, the piezoelectric layer 12 can be AlN based layer doped with Sc. According to some of these applications, the piezoelectric layer 12 of the BAW device 10 can be an AlN based piezoelectric layer doped with 3% to 45% Sc. Doping the piezoelectric layer 12 can adjust the resonant frequency. Doping the first piezoelectric layer 12 can increase the kt² of the BAW device 10. Doping to increase the kt² can be advantageous at higher frequencies where kt² can be degraded.

In certain applications, a BAW device in accordance with any suitable principles and advantages disclosed herein can include two or more piezoelectric layers stacked with each other between electrodes of a BAW device. The stacked piezoelectric layers can have c-axes oriented in opposite directions in the main acoustically active region and excite an overtone mode as a main mode of a BAW resonator.

The piezoelectric layer 12 is positioned between the first electrode 22 and the second electrode 24 in a first direction (e.g., a vertical direction) and between portions of the dielectric layer 14 in a second direction (e.g., a lateral direction or a horizontal direction) different from the first direction in the main acoustically active region 16 of the BAW device 10. The first electrode 22 is spaced apart from the second electrode 24 in the first direction. The first direction can be orthogonal to the second direction. The dielectric layer 14 can laterally surround the piezoelectric layer 12 in some applications. The dielectric layer 14 is positioned between the first electrode 22 and the second electrode 24 in the first direction in the frame region 15 of the BAW device 10.

The first electrode 22 can be referred to as a lower electrode. The first electrode 22 can have a relatively high acoustic impedance. The first electrode 22 can include molybdenum (Mo), tungsten (W), ruthenium (Ru), chromium (Cr), iridium (Ir), platinum (Pt), Ir/Pt, or any suitable alloy and/or combination thereof. Similarly, the second electrode 22 can have a relatively high acoustic impedance. The second electrode 24 can include Mo, W, Ru, Cr, Ir, Pt, Ir/Pt, or any suitable alloy and/or combination thereof. The second electrode 24 can be formed of the same material as the first electrode 22 in certain applications. The second electrode 24 can be referred to as an upper electrode. The thickness of the first electrode 22 can be approximately the same as the thickness of the second electrode 24 in the main acoustically active region 16 of the BAW device 10.

The seed layer 31 is positioned between the first electrode 22 and the passivation layer 32. The seed layer 31 can be any suitable seed layer for depositing the first electrode 22 thereon. The passivation layer 32 can be positioned between the air cavity 28 and the first electrode 22. The passivation layer 32 can be referred to as a lower passivation layer. The passivation layer 32 can be a silicon dioxide layer or any other suitable passivation layer, such as a layer including aluminum oxide, silicon carbide, aluminum nitride, silicon nitride, silicon oxynitride, or the like.

The piezoelectric layer 12 and the electrodes 22 and 24 are positioned over a support substrate 27. The support substrate 27 can be a semiconductor substrate. The support substrate 27 can be a silicon substrate. The support substrate 27 can be any other suitable support substrate, such as a as a substrate of quartz, silicon carbide, sapphire, glass, or any suitable ceramic (e.g., spinel, alumina, etc.).

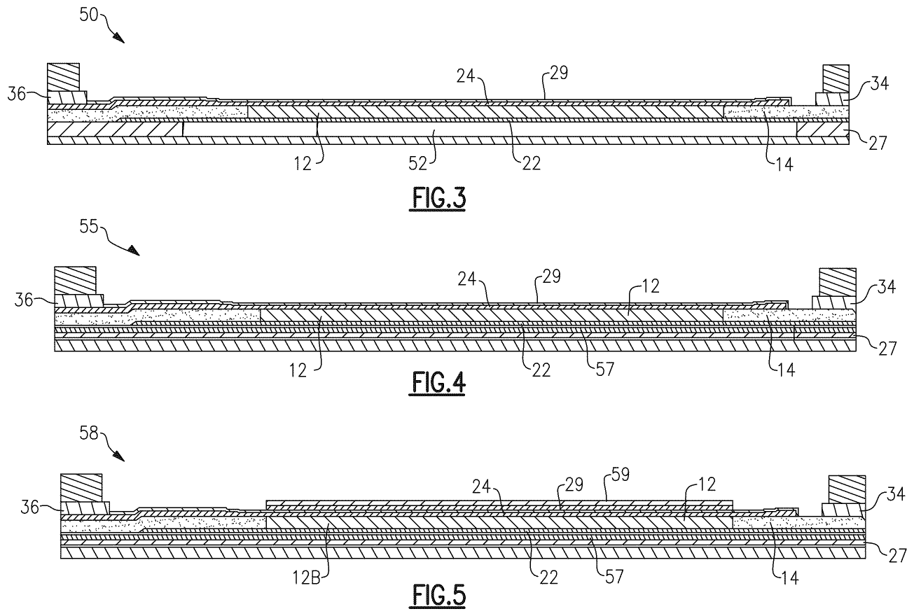

As illustrated in FIG. 1A, the air cavity 28 is located above the support substrate 27. The air cavity 28 is an example of an acoustic reflector. The air cavity 28 is positioned between the support substrate 27 and the first electrode 22. The dielectric layer 14 in the frame region 15 is positioned over the air cavity 28 in FIG. 1A. In the BAW device 10, the entire dielectric layer 14 can be positioned over the air cavity 28. In some applications, an air cavity can be etched into a support substrate, for example as shown in FIG. 3. In certain applications, a solid acoustic mirror with alternating high acoustic impedance and low acoustic impedance layers can be included in place of an air cavity, for example as shown in FIGS. 4 and 5. A BAW device with an air cavity can be referred to as a film bulk acoustic wave resonator (FBAR). A BAW device with a solid acoustic mirror can be referred to as a BAW solidly mounted resonator (SMR).

The passivation layer 29 is positioned over the second electrode 24. The passivation layer 29 can be referred to as an upper passivation layer. The passivation layer 29 can be a silicon dioxide layer or any other suitable passivation layer, such as a layer including aluminum oxide, silicon carbide, aluminum nitride, silicon nitride, silicon oxynitride, or the like. In certain applications, the passivation layer 29 and the passivation layer 32 are both the same material. The passivation layer 29 can have different thicknesses in different regions of the BAW device 10. Part of the passivation layer 29 where the passivation layer 29 is thinner can form at least part of the recessed frame structure 26. In some embodiments, the passivation layer 29 can also function as a frequency trimming layer.

The main acoustically active region 16 of the BAW device 10 corresponds to the piezoelectric layer 12 positioned laterally between potions of the dielectric layer 14. In the main acoustically active region 16, the piezoelectric layer 12 overlaps with the air cavity 28 and is between the first electrode 22 and the second electrode 24. Voltage is applied on opposing sides of the piezoelectric layer 12 in the main acoustically active region 16 to generate a bulk acoustic wave in the piezoelectric layer 12. The main acoustically active region 16 can provide a main mode of the BAW device 10. The main mode can be associated with the highest coupling or highest kt² of the modes of the BAW device 10. The main acoustically active 16 region can be the central part of the active region that is free from the dielectric layer 14 and is free from frame structures, such as the recessed frame structure 26 and the raised frame structure 25.

The frame region 15 includes the raised frame structure 25 and the recessed frame structure 26 in the BAW device 10. The raised frame structure 25 is illustrated as being a metal raised frame structure in FIG. 1A. The raised frame structure 25 can be formed of the same material as the second electrode 24. In some other applications, a raised frame structure can include a dielectric layer. Some other example raised frame structures will be discussed later.

While the BAW device 10 includes the raised frame structure 25 and recessed frame structure 26, other frame structures can alternatively or additionally be implemented. For example, a raised frame structure with multiple layers can be implemented. The multiple layers can include a layer between an electrode of a BAW device and a piezoelectric layer. As another example, a floating raised frame structure can be implemented. As one more example, a raised frame structure can be implemented without a recessed frame structure. As one more example, a recessed frame structure can be implemented without a raised frame structure.

One or more conductive layers 34 and 36 can connect an electrode of the BAW device 10 to one or more other BAW devices, one or more integrated passive devices, one or more other circuit elements, one or more signal ports, the like, or any suitable combination thereof.

FIG. 1B is an example plan view of the BAW device 10 of FIG. 1A. The cross-sectional view of FIG. 1A can be along the line from A to A′ in FIG. 1B. In FIG. 1B, the frame region 15 and the main acoustically active region 16 are shown. As illustrated, the main acoustically active region 16 can correspond to the majority of the area of the BAW device 10. The frame region 15 at least partially surrounds (e.g., completely surrounds) the main acoustically active region 16 in plan view. The frame region 15 includes the recessed frame structure 26 and the raised frame structure 25 of the BAW device 10 of FIG. 1A.

FIG. 1B illustrates the BAW device 10 with a pentagon shape with curved sides in plan view. A BAW device in accordance with any suitable principles and advantages disclosed herein can have any other suitable shape in plan view, such as a semi-elliptical shape, a semi-circular shape, a circular shape, an ellipsoid shape, a quadrilateral shape, or a quadrilateral shape with curved sides. FIG. 1C illustrates another example plan view of the BAW device 10 of FIG. 1A. In FIG. 1C, the frame region 15 and the main acoustically active region 16 are shown.

FIG. 2A is a cross-sectional diagram of a BAW device 40 including a piezoelectric layer 12 and a dielectric layer 14 according to an embodiment. The BAW device 40 is similar to the BAW device 10 of FIG. 1A, except that the dielectric layer 14 in the BAW device 40 covers less area of the BAW device 40 than the dielectric layer 14 in the BAW device 10. The dielectric layer 14 may not extend beyond the frame region 15 away from the main acoustically active region 16 of the BAW device 40. As illustrated, the dielectric layer 14 extends to an edge of the frame region 15 away from the main acoustically active region 16. In the BAW device 40, a footprint of the dielectric layer 14 corresponds to the frame region 15.

FIG. 2B is a schematic cross-sectional side view of a portion of a BAW device 42 including a piezoelectric layer 12 and a dielectric layer 14 according to an embodiment. Unless otherwise noted, the components of the BAW device 42 shown in FIG. 2B may be structurally and/or functionally the same as or generally similar to like components of other BAW devices disclosed herein. The piezoelectric layer 12 shown in FIG. 2B is positioned between portions of a dielectric layer 14 that extends into an intermediate region 102. The intermediate region 102 is between the frame region 15 and the main acoustically active region 16 in the BAW device 42. The BAW device 42 includes a raised frame layer 43 positioned between the dielectric layer 14 and the second electrode 24. The raised frame layer 43 can be any suitable raised frame layer such as a dielectric raised frame layer, an oxide raised frame layer, or a metal raised frame layer.

FIG. 2C is a schematic cross-sectional side view of a portion of a BAW device 44 including temperature compensation layer 46 according to an embodiment. The BAW device 44 also includes a piezoelectric layer 12 between portions of a dielectric layer 14. Unless otherwise noted, the components of the BAW device 44 shown in FIG. 2C may be structurally and/or functionally the same as or generally similar to like components of other BAW devices disclosed herein. The BAW device 44 of FIG. 2C is generally similar to the BAW device 42 of FIG. 2B, except that the BAW device 44 also includes a temperature compensation layer 46 between the piezoelectric layer 12 and the second electrode 24. The temperature compensation layer 46 can also be positioned between the dielectric layer 14 and the second electrode 24. In some embodiments, the temperature compensation layer 46 can include silicon oxide (e.g., silicon dioxide (SiO₂)). The temperature compensation layer 46 can bring the temperature coefficient of frequency (TCF) of the BAW device 44 closer to zero than a similar BAW device without the temperature compensation layer 46. The temperature compensation layer 46 can have a positive TCF. The temperature compensation layer 46 can be in physical contact with the piezoelectric layer 12 and/or the second electrode 24. The temperature compensation layer 46 can be over the second electrode 24 or embedded in the second electrode 24 in some other applications. Alternatively or additionally, a temperature compensation can be between the piezoelectric layer 12 and the first electrode 22, embedded in the second electrode 22, or embedded in the piezoelectric layer 12. Any suitable principles and advantages of the BAW devices disclosed herein can be implemented in BAW devices that include a temperature compensation layer.

### BAW Devices With Various Acoustic Reflectors and Piezoelectric Layer Positioned Between Portions of Dielectric Layer

The BAW devices with a piezoelectric layer positioned between portions of a dielectric layer disclosed herein can be implemented in a variety of different BAW devices. Such BAW devices can include any suitable acoustic reflector. Example BAW devices with different acoustic reflectors than the BAW device 10 of FIG. 1A are shown in FIGS. 3 to 5. Any suitable principles and advantages of these BAW devices can be implemented together with each other and/or with any suitable principles and advantages of other embodiments disclosed herein.

FIG. 3 is a cross-sectional diagram of a BAW device 50 including an air cavity 52 etched into a substrate 27 and a piezoelectric layer 12 positioned between portions of a dielectric layer 14 according to an embodiment. As illustrated in FIG. 3, the dielectric layer 14 can extend beyond an acoustic reflector, such as the air cavity 52. A portion of the dielectric layer 14 vertically overlaps with a raised frame structure over the acoustic reflector in the BAW device 50. Any suitable principles and advantages disclosed herein with reference to BAW devices with an air cavity over a substrate can be applied to BAW devices with an air cavity etched into a substrate.

FIG. 4 is a cross-sectional diagram of a BAW device 55 including a solid acoustic mirror 57 and a piezoelectric layer 12 positioned between portions of a dielectric layer 14 according to an embodiment. The BAW device 55 is a BAW solidly mounted resonator (SMR). The BAW device 55 includes a solid acoustic mirror 57 in place of an air cavity as an acoustic reflector. The solid acoustic mirror 57 is an acoustic Bragg reflector. The solid acoustic mirror 57 includes alternating low acoustic impedance layers and high acoustic impedance layers. As one example, the solid acoustic mirror 57 can include alternating silicon dioxide layers as low acoustic impedance layers and tungsten layers as high acoustic impedance layers. Any suitable principles and advantages disclosed herein with reference to FBARs be applied to BAW SMRs.

FIG. 5 is a cross-sectional diagram of a BAW device 58 including a dual solid acoustic mirror and a piezoelectric layer 12 positioned between portions of a dielectric layer 14 according to an embodiment. The BAW device 58 is like the BAW device 55 of FIG. 4, except that the BAW device 58 includes a second solid acoustic mirror 59 positioned over the second electrode 24. In the BAW device 58, the piezoelectric layer 12 and electrodes 22 and 24 are positioned between the solid acoustic mirror 56 and the second solid acoustic mirror 59 in the main acoustically active region. The frame region of the BAW device 58 can be free from the second solid acoustic mirror 59. The frame region of the BAW device 58 overlaps with the acoustic mirror 57 in the BAW device 58. A raised frame structure of the BAW device 58 overlaps with the acoustic mirror 57 in the BAW device 58.

### BAW Devices With Various Frame Structures and Dielectric Layer

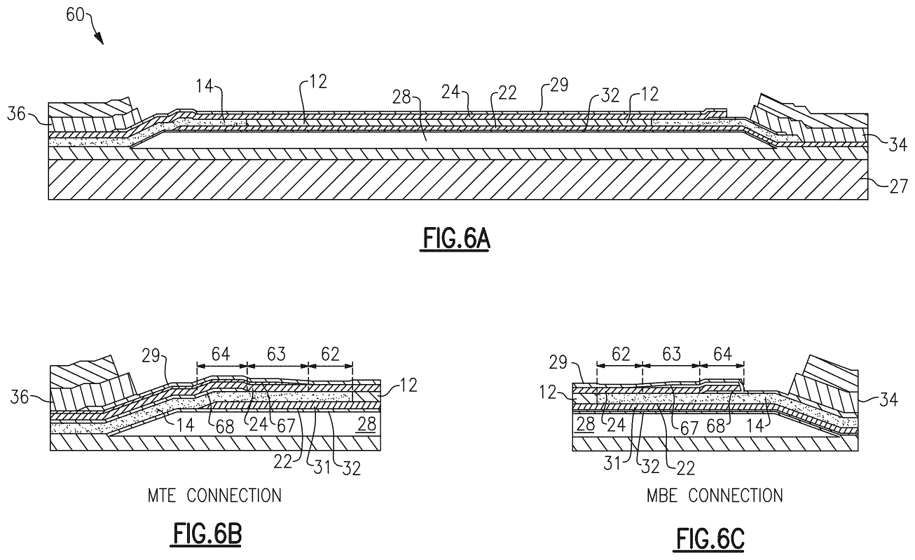

BAW devices that include a piezoelectric layer positioned between portions of a dielectric layer can include a variety of different frame structures. Such frame structures can reduce lateral energy leakage from a main acoustically active region of a BAW device. Example BAW devices with various frame structures are shown in FIGS. 6A to 9. Any suitable principles and advantages of these BAW devices can be implemented together with each other and/or with any suitable principles and advantages of other embodiments disclosed herein.

A BAW device in accordance with any suitable principles and advantages disclosed herein can include a frame structure with any suitable number of raised frame layers. A raised frame structure can include a metal raised frame layer and/or a dielectric raised frame layer. A BAW device in accordance with any suitable principles and advantages disclosed herein can include a frame structure with any suitable number of recessed frame structures. A recessed frame structure can include a thinner portion of one or more of a dielectric layer, a metal layer, or a piezoelectric layer in a recessed frame region. A BAW device in accordance with any suitable principles and advantages disclosed herein can include a frame structure without any recessed frame structures. A BAW device in accordance with any suitable principles and advantages disclosed herein can include a frame structure without any raised frame structures.

FIG. 6A is a cross-sectional diagram of a BAW device 60 including a plurality of raised frame layers and a piezoelectric layer 12 positioned between portions of a dielectric layer 14 according to an embodiment. The BAW device 60 also includes an air cavity 28 over a substrate 27. The BAW device 60 is similar to the BAW device 40 of FIG. 2A, except that the BAW device 60 includes a different frame structure and the dielectric layer 14 in the BAW device 60 extends further in a direction away from the main acoustically active region in the BAW device 60. The dielectric layer 14 extends beyond the air cavity 28 in the BAW device 60.

FIG. 6B is a zoomed in view of a metal top electrode connection area of the BAW device 60 that includes the frame region. The second electrode 24 is the top electrode in the BAW device 60. In FIG. 6B, the second electrode 24 connects to conductive layer 36. FIG. 6C is a zoomed in view of the frame region near a bottom electrode connection area of the BAW device 60. The first electrode 22 is the bottom electrode in the BAW device 60. The first electrode 22 connects to conductive layer 34 beyond the zoomed in portion shown in FIG. 6C.

Referring to FIGS. 6B and 6C, the frame region of the BAW device 60 includes a recessed frame region 62, a first raised frame region 63, and a second raised frame region 64. Raised frame regions can include one or more raised frame layers. A raised frame layer can be a metal layer, an oxide layer, or any other suitable layer. The BAW device 60 includes an additional raised frame layer in the second raised frame region 64 relative to in the first raised frame region 63. A recessed frame structure can include one or more layers that are thinner in a recessed frame region than in the main acoustically active region.

In the recessed frame region 62 of the BAW device 60, the passivation layer 29 is thinner than in the main acoustically active region of the BAW device 60. Such a recessed frame structure can be formed, for example, by etching the passivation layer 29 in the recessed frame region 62. In some other applications, such a recessed frame structure can be formed by forming additional passivation material of the passivation layer 29 in regions of the BAW device 60 outside of the recessed frame region 62. The passivation layer 29 can include, but is not limited to, one or more of silicon dioxide (SiO₂), silicon nitride (Si₃N₄), aluminum oxide (Al₂O₃), aluminum nitride (AlN), a carbide, a boride, hafnium dioxide (HfO₂), or tantalum pentoxide (Ta₂O₅).

Although the BAW device 60 includes a thinner passivation layer 29 in the recessed frame region 62 than in the main acoustically active region, a recessed frame structure of a BAW device can alternatively or additionally include one or more of a thinner second electrode, a thinner dielectric layer, a thinner first electrode, or a thinner seed layer in the recessed frame region than in the main acoustically active region.

The BAW device 60 includes a metal raised frame layer 67 in the first raised frame region 63. As illustrated, the metal raised frame layer 67 is positioned between the second electrode 24 and the passivation layer 29. With a metal raised frame layer 67, the first raised frame region 63 can be referred to as a metal raised frame region. A metal raised frame layer can alternatively or additionally be positioned in any other suitable position in the material stack of a BAW device. In certain applications, the metal raised frame layer 67 includes a same material as the second electrode 24. The metal raised frame layer 67 can include any suitable metal.

The BAW device 60 includes the metal raised frame layer 67 and an oxide raised frame layer 68 in the second raised frame region 64. With an oxide raised frame layer 68, the second raised frame region 64 can be referred to as an oxide raised frame region. As illustrated, the oxide raised frame layer 68 is positioned at least partially between the dielectric layer 14 and the second electrode 24. An oxide raised frame layer can alternatively or additionally be positioned in any other suitable position in the material stack of a BAW device. The oxide raised frame layer 68 can be a silicon dioxide layer, for example. Any other suitable passivation layer or any other suitable dielectric layer can be implemented in place of the oxide raised frame layer.

Frame structures of a BAW device can have the same or different dimensions on a metal top electrode connection side as on a metal bottom electrode side. Raised frame structures of a BAW device can have the same or different dimensions on a metal top electrode connection side as on a metal bottom electrode side. The materials of the frame structures on the metal top electrode connection side can be the same or different as on the metal bottom electrode side in a BAW device.

Although the illustrated BAW device 60 includes the recessed frame region 62, the first raised frame region 63, and the second raised frame region 64, a BAW device in accordance with any suitable principles and advantages disclosed herein can include one or more suitable frame structures in some other embodiments. For example, there may be only one of the recessed frame region 62, the first raised frame region 63, and the second raised frame region 64 in a BAW device. In the case that a BAW device includes a single raised frame layer, the single raised frame layer can be any suitable raised frame layer such as, but not limited to, an oxide raised frame layer or a metal raised frame layer. As another example, there may be only two of the recessed frame region 62, the first raised frame region 63, and the second raised frame region 64 in a BAW device.

In some applications, a BAW device with a piezoelectric layer positioned between portions of a dielectric layer in accordance with any suitable principles and advantages disclosed herein can be implemented without a frame structure. A BAW device without a frame structure and a dielectric region generally aligned with an edge of the active region of the BAW device can achieve a desirable Qp for certain applications. As one example, such a BAW device can be a BAW resonator for an ultra high band filter, where the BAW resonator a relatively small area. In some applications, a BAW device without a frame structure can include a dielectric layer vertically overlapping with a frame structure, where the dielectric layer extends beyond the acoustic reflector away from the main acoustically active region of the BAW device. In certain applications, a BAW device without a frame structure can include a dielectric layer vertically overlapping with a frame structure, where the that piezoelectric layer overlaps with a single electrode of the BAW device over the acoustic reflector on a side of the dielectric layer away from the main acoustically active region of the BAW device.

FIG. 7 is a cross-sectional diagram of a BAW device 70 including a piezoelectric layer 12 positioned between portions of a dielectric layer 14 according to an embodiment. The BAW device 70 includes a suspended frame region 72. The BAW device 70 also includes a recessed frame region 62, a first raised frame region 63, and a second raised frame region 64. The dielectric layer 14 can suppress and/or eliminate spurious modes from each of the frame regions of the BAW device 70.

A raised frame layer can be included in any suitable position in a material stack of a BAW device. BAW devices can include raised frame layers on opposing sides of a piezoelectric layer. BAW devices can include a raised frame layer embedded in a piezoelectric layer. BAW devices can include a plurality of raised frame layers on a same side of the piezoelectric layer.

In some applications, the frame structure on a metal top electrode connection side of a BAW device can be different than the frame structure on a metal bottom electrode side of the BAW device. For example, raised frame structures can have different geometries on the metal top electrode connection side and the metal bottom electrode side of a BAW device. As another example, a raised frame layer (e.g., a dielectric layer) can be included on a metal top electrode connection side of a BAW device and not included on a metal bottom electrode side of the BAW device.

Some BAW devices can include a raised frame layer on a side of the piezoelectric layer that is opposite the acoustic reflector and another raised frame layer either embedded in the piezoelectric layer or on the opposite side of the piezoelectric layer than the raised frame layer.

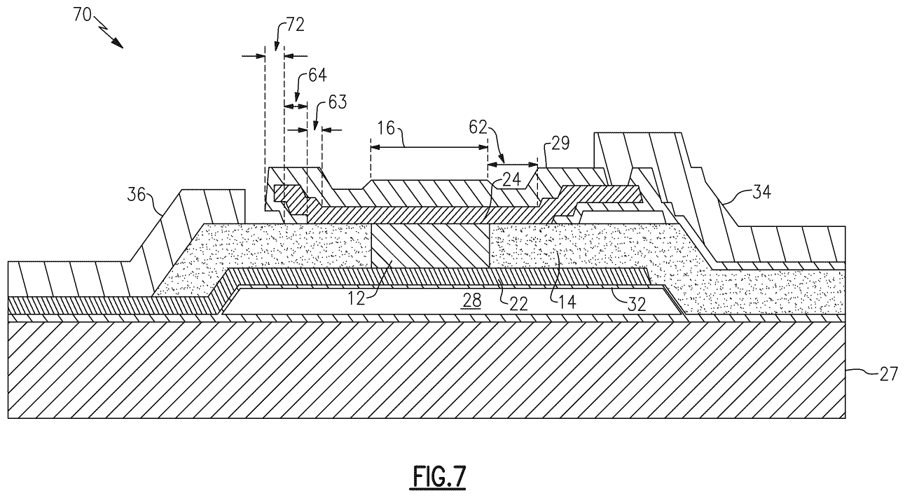

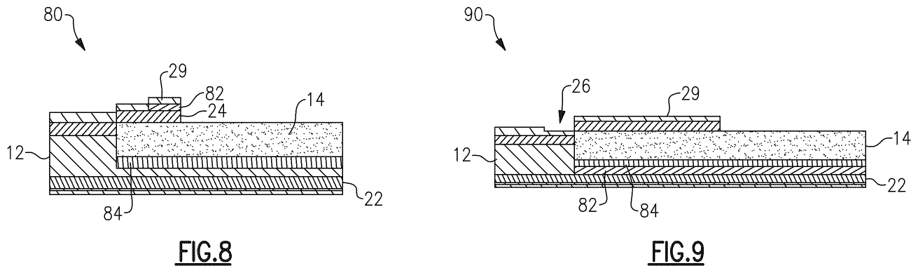

FIG. 8 is a cross-sectional diagram of a portion of a BAW device 80 including a piezoelectric layer 12 positioned at least partially between portions of a dielectric layer 14 according to an embodiment. The BAW device 80 includes a first raised frame layer 82 and a second raised frame layer 84.

The first raised frame layer 82 is over the dielectric layer 14 on a side opposite to the acoustic reflector (not illustrated in FIG. 8) and support substrate (not illustrated in FIG. 8) of the BAW device 80. The first raised frame layer 82 is positioned between the second electrode 24 and the passivation layer 29. The first raised frame layer 82 can be a metal layer or a dielectric layer. For example, the first raised frame layer 82 can be a metal layer that is the same material as the second electrode 24. In some other applications, the first raised frame layer 82 can be a dielectric layer that is the same material as the passivation layer 29.

The second raised frame layer 84 is positioned below material of the dielectric layer 14 in the BAW device 80. In some other applications, the second raised frame layer 84 can be embedded in the dielectric layer 14. Although the second raised frame layer 84 is show as being deposited over material of the piezoelectric layer 12, a second raised frame layer can alternatively or additionally be deposited over the first electrode 22 and below the entire dielectric layer 14 in some other applications. The second raised frame layer 84 can be a metal layer or a dielectric layer of a different material than the dielectric layer 14. A thickness of the second raised frame layer 84 can be in a range from greater than zero to less than a maximum thickness of the piezoelectric layer 12. In the BAW device 80, a relatively thin portion of the piezoelectric layer 12 can extend below the dielectric layer 14 and below the second raised frame layer 84. A thickness of the piezoelectric layer 12 below the second raised frame layer 84 can be in a range from zero to less than a maximum thickness of the piezoelectric layer 12.

The BAW device 80 includes two raised frame regions in which a raised frame structure is located and the piezoelectric layer 12 and/or the dielectric layer 14 is positioned between the electrodes 22 and 24. In a first raised frame region of the BAW device 80, only the second raised frame layer 84 is present. The first raised frame layer 82 and the second raised frame layer 84 overlap in a second raised frame region of the BAW device 80. The first raised frame layer 82 and the second raised frame layer 84 can have different widths. For example, in the BAW device 80, the second raised frame layer 84 has a greater width than the first raised frame layer 82.

As illustrated in FIG. 8, the BAW device 80 does not include a recessed frame structure. In some other applications, the raised frame structure of the BAW device 80 can be implemented in a BAW device that also includes a recessed frame structure.

Some BAW devices can include a plurality of raised frame layers on a side of the piezoelectric layer that faces the acoustic reflector. An example of such a BAW device will be discussed with reference to FIG. 9.

FIG. 9 is a cross-sectional diagram of a portion of a BAW device 90 including a piezoelectric layer 12 positioned between portions of a dielectric layer 14 according to an embodiment. The BAW device 90 includes a first raised frame layer 82 and a second raised frame layer 84 that are both positioned between the dielectric layer 14 and the first electrode 22. In the BAW device 90, the first raised frame layer 82 and the second raised frame layer 84 are on a side of the dielectric layer 14 that faces the acoustic reflector (not illustrated in FIG. 9). The first raised frame layer 82 and the second raised frame layer 84 can be in physical contact each other in the BAW device 90. In some other applications, there can be an intervening layer or an air gap between the first raised frame layer 82 and the second raised frame layer 84 in a BAW device similar to the BAW device 90. The first raised frame layer 82 and the second raised frame layer 84 can have equal widths. In some other applications, the first raised frame layer 82 and the second raised frame layer 84 can have different widths. As illustrated in FIG. 9, the BAW device 90 includes a recessed frame structure 26. In some other applications, the raised frame structure of the BAW device 90 can be implemented in a BAW device that does not include a recessed frame structure.

### Positions of Dielectric Layer and Piezoelectric Layer in BAW Devices

To achieve a higher Quality factor at parallel resonance (Qp), a piezoelectric layer can be positioned between portions of dielectric layer that is in at least a frame region. Such a frame region can include one or more raised frame regions and/or one or more recessed frame regions. Lower Qp may be achieved when the dielectric layer does not span the frame region relative to when the dielectric layer spans the frame region. Accordingly, the dielectric layer can at least span the frame region that includes all raised frame region(s) and/or recessed frame region(s) of the BAW device.

In some applications, an edge of the dielectric layer can align with an edge of the frame region on a side adjacent to the main acoustically active region. The dielectric layer can extend into an intermediate region that is between the frame region and the main acoustically active region. When the dielectric layer extends into such an intermediate region, Q can be improved, kt² can be relatively stable, frame modes (e.g., raised frame modes and/or recessed frame modes) can be suppressed, and the same or a similar level of lateral mode intensity can be present between fd and fs.

FIG. 10 a cross-sectional diagram of a portion of a BAW device 100 including a piezoelectric layer 12 positioned between portions of a dielectric layer 14 that extends into an intermediate region 102 of the BAW device 100 according to an embodiment. The intermediate region 102 is between the frame region 15 and the main acoustically active region 16 in the BAW device 100. The dielectric layer 14 can extend beyond the frame region 15 toward the main acoustically active region 16 to ensure that the dielectric layer 14 spans the entire frame region 15 even with offsets and/or other variations in manufacturing. The BAW device 100 can achieve desirable Q and suppress and/or eliminate frame modes.

In some embodiments such as the BAW device 10 of FIG. 1A, an edge of the dielectric layer can align with an edge of the frame region on a side opposite to the main acoustically active region. Alternatively, in some other embodiments such as the BAW device 40 of FIG. 2A, the dielectric layer can extend into an outer region that is on an opposite side of a frame region than the main acoustically active region.

### Methods of Manufacturing BAW Device With Piezoelectric Layer Positioned Between Portions of Dielectric Layer

BAW devices that include a piezoelectric layer positioned at least partially between portions of a dielectric layer in accordance with any suitable principles and advantages disclosed herein can be manufactured using a variety of methods. The dielectric layer can be provided after forming the piezoelectric layer. In some other embodiments, the dielectric layer can be formed prior to forming the piezoelectric layer. A BAW device can be manufactured in accordance with any suitable principles and advantages of any of the methods disclosed herein.

FIG. 11 is a flow diagram of a method 140 of manufacturing a BAW device according to an embodiment. The method 140 can be performed to form any suitable BAW device in accordance with any suitable principles and advantages disclosed herein.

The method 140 includes providing a piezoelectric material over a first electrode in block 142. This can involve providing the piezoelectric material by way of deposition. The piezoelectric material can be provided in a main acoustically active region as well as in the peripheral region. The peripheral region can include the frame region. In some instances, the peripheral region can include an outer region on an opposite side of the frame region than the main acoustically active region. Alternatively or additionally, the peripheral region can include an intermediate region between the frame region than the main acoustically active region. A portion of the provided piezoelectric material in the peripheral region can be removed to define the piezoelectric layer.

The method 140 includes providing dielectric material in a cavity defined by the removed portion of the piezoelectric material in block 143. The dielectric material can at least partially fill the cavity. In some embodiments, the dielectric material can overfill the cavity, and an excess portion of the dielectric material can be removed to define the dielectric layer.

The method 140 includes depositing a second electrode over the piezoelectric layer and the dielectric layer at block 144. After the second electrode is formed, the piezoelectric layer is positioned between the first electrode and the second electrode in the main acoustically active region. The dielectric layer can be positioned between the first electrode and the second electrode in the frame region in a BAW device after manufacture of the BAW device is complete. The method 140 can include forming one or more other layers and/or structures of one or more of the BAW devices disclosed herein. In some instances, the method 140 can include electrically connecting the BAW device with another BAW device of an acoustic wave filter.

BAW devices according to various embodiments disclosed herein can be manufactured by any other suitable methods. For example, a method of manufacturing a BAW device can include selectively forming a piezoelectric layer at least in a main acoustically active region of the BAW device, and providing a dielectric material at least in a frame region of the BAW device.

### Applications for BAW Device With Piezoelectric Layer Positioned Between Portions of Dielectric Layer

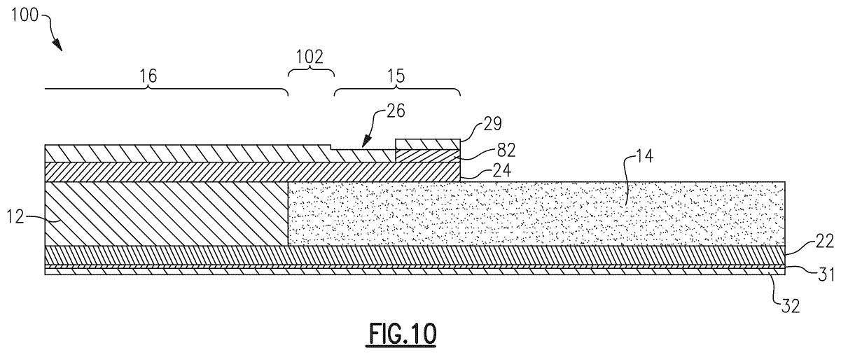

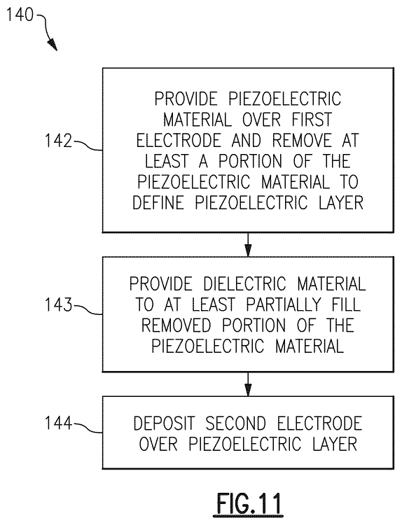

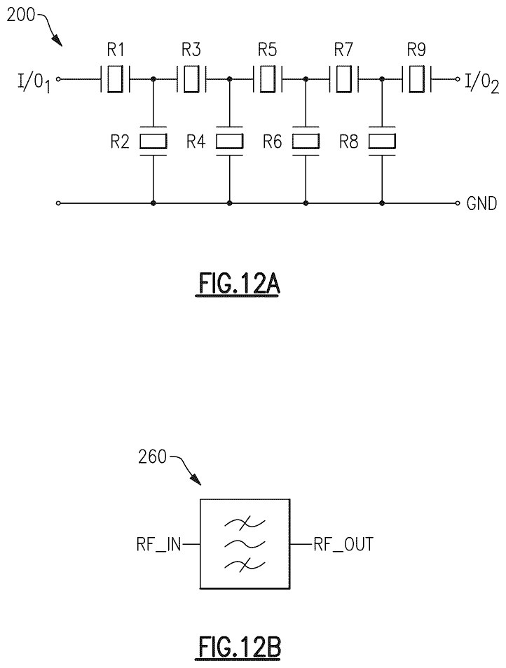

BAW devices disclosed herein can be implemented as BAW resonators in a variety of filters. Such filters can be arranged to filter a radio frequency signal. A BAW device of such a filter can have a resonant frequency of greater than 2.5 GHz. The resonant frequency of the BAW device can be in a range from 2.5 GHz to 7 GHz. BAW devices disclosed herein can be implemented in a variety of different filter topologies. Example filter topologies include without limitation, ladder filters, lattice filters, hybrid ladder lattice filters, notch filters where a notch is created by an acoustic wave resonator, hybrid acoustic and non-acoustic inductor-capacitor filters, and the like. The example filter topologies can implement band pass filters. The example filter topologies can implement band stop filters. In some instances, acoustic wave devices disclosed herein can be implemented in filters with one or more other types of resonators and/or with passive impedance elements, such as one or more inductors and/or one or more capacitors. An example filter topology will be discussed with reference to FIG. 12A.

FIG. 12A is a schematic diagram of a ladder filter 200 that includes an acoustic wave resonator according to an embodiment. The ladder filter 200 is an example topology that can implement a band pass filter formed of acoustic wave resonators. In a band pass filter with a ladder filter topology, the shunt resonators can have lower resonant frequencies than the series resonators. The ladder filter 200 can be arranged to filter a radio frequency signal. As illustrated, the ladder filter 200 includes series acoustic wave resonators R1 R3, R5, R7, and R9 and shunt acoustic wave resonators R2, R4, R6, and R8 coupled between a first input/output port I/O₁ and a second input/output port I/O₂. Any suitable number of series acoustic wave resonators can be included in a ladder filter. Any suitable number of shunt acoustic wave resonators can be included in a ladder filter. The first input/output port I/O₁ can be a transmit port and the second input/output port I/O₂ can be an antenna port. Alternatively, first input/output port I/O₁ can be a receive port and the second input/output port I/O₂ can be an antenna port. One or more of the acoustic wave resonators of the ladder filter 200 can include a BAW resonator in accordance with any suitable principles and advantages disclosed herein. All acoustic resonators of the ladder filter 200 can include a BAW resonator in accordance with any suitable principles and advantages disclosed herein.

A filter that includes a BAW resonator in accordance with any suitable principles and advantages disclosed herein be arranged to filter a radio frequency signal in a fifth generation 5G NR operating band within Frequency Range 1 (FR1). FR1 can be from 410 MHz to 7.125 gigahertz (GHz), for example, as specified in a current 5G NR specification. A filter that includes an acoustic wave resonator in accordance with any suitable principles and advantages disclosed herein can be arranged to filter a radio frequency signal in a fourth generation (4G) Long Term Evolution (LTE) operating band. A filter that includes an acoustic wave resonator in accordance with any suitable principles and advantages disclosed herein can be included in a filter having a passband that includes a 4G LTE operating band and a 5G NR operating band. Such a filter can be implemented in a dual connectivity application, such as an E-UTRAN New Radio-Dual Connectivity (ENDC) application. A multiplexer including any such filters can include one or more other filters with a passband corresponding to a 5G NR operating band and/or a 4G LTE operating band.

The BAW resonators disclosed herein can be advantageous for implementing BAW devices with relatively high Qp and relatively low spur intensity. BAW resonators disclosed herein can have significantly better performance than a variety of other BAW resonators. This can be advantageous in meeting demanding specifications for acoustic wave filters, such as performance specifications for certain 5G applications.

FIG. 12B is schematic diagram of an acoustic wave filter 260. The acoustic wave filter 260 can include the acoustic wave resonators of the ladder filter 200. The acoustic wave filter 260 is a band pass filter. The acoustic wave filter 260 is arranged to filter a radio frequency signal. The acoustic wave filter 260 includes one or more acoustic wave devices coupled between a first input/output port RF_IN and a second input/output port RF_OUT. The acoustic wave filter 260 includes a BAW resonator according to an embodiment.

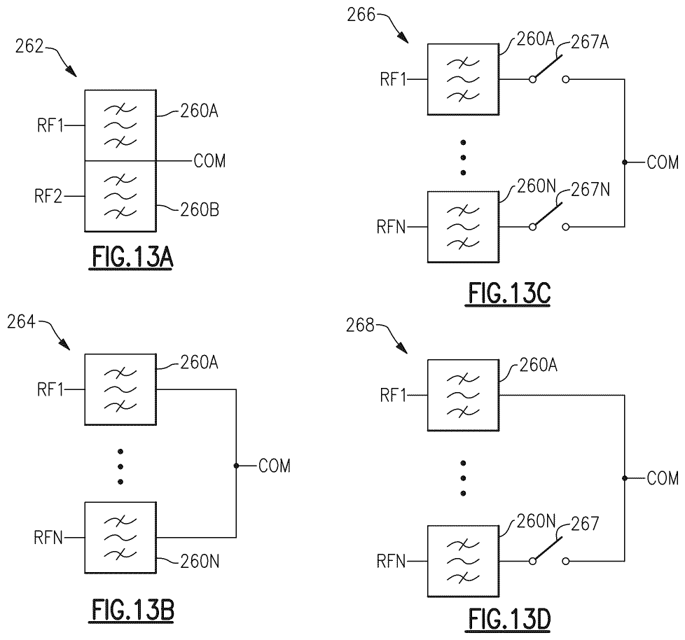

The BAW devices disclosed herein can be implemented in a standalone filter and/or in a filter of any suitable multiplexer. Such filters can be any suitable topology, such as a ladder filter topology. The filter can be a band pass filter arranged to filter a 4G LTE band and/or 5G NR band. Example multiplexers will be discussed with reference to FIGS. 13A to 13D. Any suitable principles and advantages of these multiplexers can be implemented together with each other.

FIG. 13A is a schematic diagram of a duplexer 262 that includes an acoustic wave filter according to an embodiment. The duplexer 262 includes a first filter 260A and a second filter 260B coupled together at a common node COM. One of the filters of the duplexer 262 can be a transmit filter and the other of the filters of the duplexer 262 can be a receive filter. In some other instances, such as in a diversity receive application, the duplexer 262 can include two receive filters. Alternatively, the duplexer 262 can include two transmit filters. The common node COM can be an antenna node.

The first filter 260A is an acoustic wave filter arranged to filter a radio frequency signal. The first filter 260A includes one or more acoustic wave resonators coupled between a first radio frequency node RF1 and the common node COM. The first radio frequency node RF1 can be a transmit node or a receive node. The first filter 260A includes a BAW resonator in accordance with any suitable principles and advantages disclosed herein.

The second filter 260B can be any suitable filter arranged to filter a second radio frequency signal. The second filter 260B can be, for example, an acoustic wave filter, an acoustic wave filter that includes a BAW resonator in accordance with any suitable principles and advantages disclosed herein, an LC filter, a hybrid acoustic wave LC filter, or the like. The second filter 260B is coupled between a second radio frequency node RF2 and the common node. The second radio frequency node RF2 can be a transmit node or a receive node.

Although example embodiments may be discussed with filters or duplexers for illustrative purposes, any suitable principles and advantages disclosed herein can be implement in a multiplexer that includes a plurality of filters coupled together at a common node. Examples of multiplexers include but are not limited to a duplexer with two filters coupled together at a common node, a triplexer with three filters coupled together at a common node, a quadplexer with four filters coupled together at a common node, a hexaplexer with six filters coupled together at a common node, an octoplexer with eight filters coupled together at a common node, or the like. Multiplexers can include filters having different passbands. Multiplexers can include any suitable number of transmit filters and any suitable number of receive filters. For example, a multiplexer can include all receive filters, all transmit filters, or one or more transmit filters and one or more receive filters. One or more filters of a multiplexer can include any suitable number of acoustic wave devices in accordance with any suitable principles and advantages disclosed herein.

FIG. 13B is a schematic diagram of a multiplexer 264 that includes an acoustic wave filter according to an embodiment. The multiplexer 264 includes a plurality of filters 260A to 260N coupled together at a common node COM. The plurality of filters can include any suitable number of filters including, for example, 3 filters, 4 filters, 5 filters, 6 filters, 7 filters, 8 filters, or more filters. Some or all of the plurality of acoustic wave filters can be acoustic wave filters. As illustrated, the filters 260A to 260N each have a fixed electrical connection to the common node COM. This can be referred to as hard multiplexing or fixed multiplexing. Filters have fixed electrical connections to the common node in hard multiplexing applications.

The first filter 260A is an acoustic wave filter arranged to filter a radio frequency signal. The first filter 260A can include one or more acoustic wave devices coupled between a first radio frequency node RF1 and the common node COM. The first radio frequency node RF1 can be a transmit node or a receive node. The first filter 260A includes a BAW resonator in accordance with any suitable principles and advantages disclosed herein. The other filter(s) of the multiplexer 264 can include one or more acoustic wave filters, one or more acoustic wave filters that include a BAW resonator in accordance with any suitable principles and advantages disclosed herein, one or more LC filters, one or more hybrid acoustic wave LC filters, the like, or any suitable combination thereof.

FIG. 13C is a schematic diagram of a multiplexer 266 that includes an acoustic wave filter according to an embodiment. The multiplexer 266 is like the multiplexer 264 of FIG. 13B, except that the multiplexer 266 implements switched multiplexing. In switched multiplexing, a filter is coupled to a common node via a switch. In the multiplexer 266, the switches 267A to 267N can selectively electrically connect respective filters 260A to 260N to the common node COM. For example, the switch 267A can selectively electrically connect the first filter 260A the common node COM via the switch 267A. Any suitable number of the switches 267A to 267N can electrically a respective filter 260A to 260N to the common node COM in a given state. Similarly, any suitable number of the switches 267A to 267N can electrically isolate a respective filter 260A to 260N to the common node COM in a given state. The functionality of the switches 267A to 267N can support various carrier aggregations.

FIG. 13D is a schematic diagram of a multiplexer 268 that includes an acoustic wave filter according to an embodiment. The multiplexer 268 illustrates that a multiplexer can include any suitable combination of hard multiplexed and switched multiplexed filters. One or more acoustic wave devices in accordance with any suitable principles and advantages disclosed herein can be included in a filter (e.g., the filter 260A) that is hard multiplexed to the common node COM of the multiplexer 268. Alternatively or additionally, one or more acoustic wave devices in accordance with any suitable principles and advantages disclosed herein can be included in a filter (e.g., the filter 260N) that is switch multiplexed to the common node COM of the multiplexer 268.

Acoustic wave devices disclosed herein can be implemented in a variety of packaged modules. Some example packaged modules will now be disclosed in which any suitable principles and advantages of the BAW devices disclosed herein can be implemented. The example packaged modules can include a package that encloses the illustrated circuit elements. A module that includes a radio frequency component can be referred to as a radio frequency module. The illustrated circuit elements can be disposed on a common packaging substrate. The packaging substrate can be a laminate substrate, for example. FIGS. 14, 15, and 16 are schematic block diagrams of illustrative packaged modules according to certain embodiments. Any suitable combination of features of these packaged modules can be implemented with each other.

FIG. 14 is a schematic diagram of a radio frequency module 270 that includes an acoustic wave component 272 according to an embodiment. The illustrated radio frequency module 270 includes the acoustic wave component 272 and other circuitry 273. The acoustic wave component 272 can include an acoustic wave filter that includes a plurality of acoustic wave devices, for example. The acoustic wave devices can be BAW devices in certain applications.

The acoustic wave component 272 shown in FIG. 14 includes one or more acoustic wave devices 274 and terminals 275A and 275B. The one or more acoustic wave devices 274 include one or more BAW devices implemented in accordance with any suitable principles and advantages disclosed herein. The terminals 275A and 274B can serve, for example, as an input contact and an output contact. Although two terminals are illustrated, any suitable number of terminals can be implemented for a particular application. The acoustic wave component 272 and the other circuitry 273 are on a common packaging substrate 276 in FIG. 14. The packaging substrate 276 can be a laminate substrate. The terminals 275A and 275B can be electrically connected to contacts 277A and 277B, respectively, on the packaging substrate 276 by way of electrical connectors 278A and 278B, respectively. The electrical connectors 278A and 278B can be bumps or wire bonds, for example.

The other circuitry 273 can include any suitable additional circuitry. For example, the other circuitry can include one or more radio frequency amplifiers (e.g., one or more power amplifiers and/or one or more low noise amplifiers), one or more radio frequency switches, one or more additional filters, one or more RF couplers, one or more delay lines, one or more phase shifters, the like, or any suitable combination thereof. Accordingly, the other circuitry 273 can include one or more radio frequency circuit elements. The other circuitry 273 can be electrically connected to the one or more acoustic wave devices 274. The radio frequency module 270 can include one or more packaging structures to, for example, provide protection and/or facilitate easier handling of the radio frequency module 270. Such a packaging structure can include an overmold structure formed over the packaging substrate 276. The overmold structure can encapsulate some or all of the components of the radio frequency module 270.

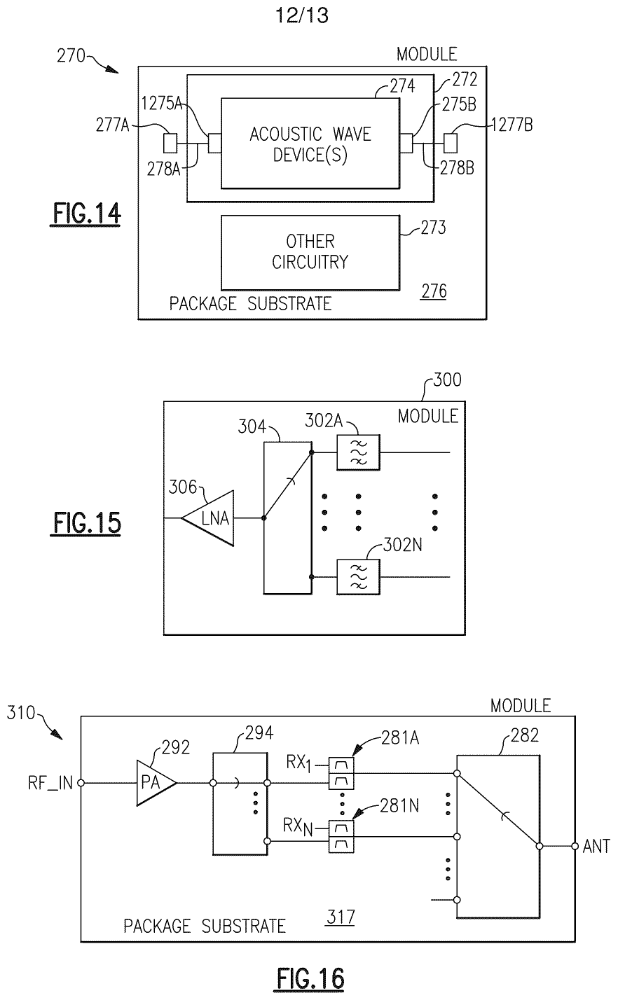

FIG. 15 is a schematic block diagram of a module 300 that includes filters 302A to 302N, a radio frequency switch 304, and a low noise amplifier 306 according to an embodiment. One or more filters of the filters 302A to 302N can include any suitable number of bulk acoustic wave devices in accordance with any suitable principles and advantages disclosed herein. Any suitable number of filters 302A to 302N can be implemented. The illustrated filters 302A to 302N are receive filters. One or more of the filters 302A to 302N can be included in a multiplexer that also includes a transmit filter and/or another receive filter. The radio frequency switch 304 can be a multi-throw radio frequency switch. The radio frequency switch 304 can electrically couple an output of a selected filter of filters 302A to 302N to the low noise amplifier 306. In some embodiments, a plurality of low noise amplifiers can be implemented. The module 300 can include diversity receive features in certain applications.

FIG. 16 is a schematic diagram of a radio frequency module 310 that includes an acoustic wave filter according to an embodiment. As illustrated, the radio frequency module 310 includes duplexers 316A to 316N, a power amplifier 312, a radio frequency switch 314 configured as a select switch, and an antenna switch 318. The radio frequency module 310 can include a package that encloses the illustrated elements. The illustrated elements can be disposed on a common packaging substrate 317. The packaging substrate 317 can be a laminate substrate, for example. A radio frequency module that includes a power amplifier can be referred to as a power amplifier module. A radio frequency module can include a subset of the elements illustrated in FIG. 16 and/or additional elements. The radio frequency module 310 may include any one of the acoustic wave filters that include at least one bulk acoustic wave resonator in accordance with any suitable principles and advantages disclosed herein.

The duplexers 316A to 316N can each include two acoustic wave filters coupled to a common node. For example, the two acoustic wave filters can be a transmit filter and a receive filter. As illustrated, the transmit filter and the receive filter can each be a band pass filter arranged to filter a radio frequency signal. One or more of the transmit filters can include a BAW device in accordance with any suitable principles and advantages disclosed herein. Similarly, one or more of the receive filters can include a BAW device in accordance with any suitable principles and advantages disclosed herein. Although FIG. 16 illustrates duplexers, any suitable principles and advantages disclosed herein can be implemented in other multiplexers (e.g., quadplexers, hexaplexers, octoplexers, etc.) and/or in switched multiplexers and/or with standalone filters.

The power amplifier 312 can amplify a radio frequency signal. The illustrated radio frequency switch 314 is a multi-throw radio frequency switch. The radio frequency switch 314 can electrically couple an output of the power amplifier 312 to a selected transmit filter of the transmit filters of the duplexers 316A to 316N. In some instances, the radio frequency switch 314 can electrically connect the output of the power amplifier 312 to more than one of the transmit filters. The antenna switch 318 can selectively couple a signal from one or more of the duplexers 316A to 316N to an antenna port ANT. The duplexers 316A to 316N can be associated with different frequency bands and/or different modes of operation (e.g., different power modes, different signaling modes, etc.).

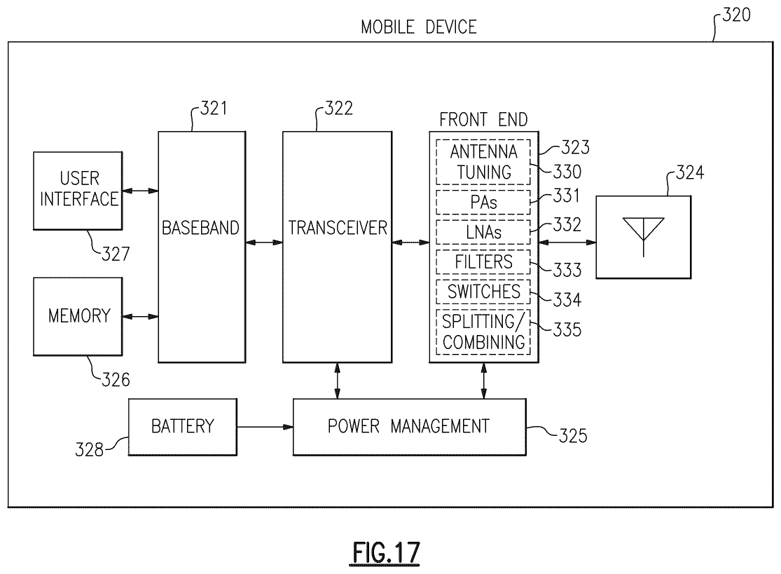

The BAW devices disclosed herein can be implemented in wireless communication devices. FIG. 17 is a schematic block diagram of a wireless communication device 320 that includes a BAW device according to an embodiment. The wireless communication device 320 can be a mobile device. The wireless communication device 320 can be any suitable wireless communication device. For instance, a wireless communication device 320 can be a mobile phone, such as a smart phone. As illustrated, the wireless communication device 320 includes a baseband system 321, a transceiver 322, a front end system 323, one or more antennas 324, a power management system 325, a memory 326, a user interface 327, and a battery 328.

The wireless communication device 320 can be used communicate using a wide variety of communications technologies, including, but not limited to, 2G, 3G, 4G (including LTE, LTE-Advanced, and/or LTE-Advanced Pro), 5G NR, WLAN (for instance, Wi-Fi), WPAN (for instance, Bluetooth and/or ZigBee), WMAN (for instance, WiMax), and/or GPS technologies.

The transceiver 322 generates RF signals for transmission and processes incoming RF signals received from the antennas 324. Various functionalities associated with the transmission and receiving of RF signals can be achieved by one or more components that are collectively represented in FIG. 17 as the transceiver 322. In one example, separate components (for instance, separate circuits or dies) can be provided for handling certain types of RF signals.

The front end system 323 aids in conditioning signals provided to and/or received from the antennas 324. In the illustrated embodiment, the front end system 323 includes antenna tuning circuitry 330, power amplifiers (PAS) 331, low noise amplifiers (LNAs) 332, filters 333, switches 334, and signal splitting/combining circuitry 335. However, other implementations are possible. The filters 333 can include one or more acoustic wave filters that include any suitable number of BAW devices in accordance with any suitable principles and advantages disclosed herein.

For example, the front end system 323 can provide a number of functionalities, including, but not limited to, amplifying signals for transmission, amplifying received signals, filtering signals, switching between different bands, switching between different power modes, switching between transmission and receiving modes, duplexing of signals, multiplexing of signals, or any suitable combination thereof.

In certain implementations, the wireless communication device 320 supports carrier aggregation, thereby providing flexibility to increase peak data rates. Carrier aggregation can be used for Frequency Division Duplexing (FDD) and/or Time Division Duplexing (TDD), and may be used to aggregate a plurality of carriers and/or channels. Carrier aggregation includes contiguous aggregation, in which contiguous carriers within the same operating frequency band are aggregated. Carrier aggregation can also be non-contiguous, and can include carriers separated in frequency within a common band or in different bands.

The antennas 324 can include antennas used for a wide variety of types of communications. For example, the antennas 324 can include antennas for transmitting and/or receiving signals associated with a wide variety of frequencies and communications standards.

In certain implementations, the antennas 324 support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The wireless communication device 320 can operate with beamforming in certain implementations. For example, the front end system 323 can include amplifiers having controllable gain and phase shifters having controllable phase to provide beam formation and directivity for transmission and/or reception of signals using the antennas 324. For example, in the context of signal transmission, the amplitude and phases of the transmit signals provided to the antennas 324 are controlled such that radiated signals from the antennas 324 combine using constructive and destructive interference to generate an aggregate transmit signal exhibiting beam-like qualities with more signal strength propagating in a given direction. In the context of signal reception, the amplitude and phases are controlled such that more signal energy is received when the signal is arriving to the antennas 324 from a particular direction. In certain implementations, the antennas 324 include one or more arrays of antenna elements to enhance beamforming.

The baseband system 321 is coupled to the user interface 327 to facilitate processing of various user input and output (I/O), such as voice and data. The baseband system 321 provides the transceiver 322 with digital representations of transmit signals, which the transceiver 322 processes to generate RF signals for transmission. The baseband system 321 also processes digital representations of received signals provided by the transceiver 322. As shown in FIG. 17, the baseband system 321 is coupled to the memory 326 of facilitate operation of the wireless communication device 320.

The memory 326 can be used for a wide variety of purposes, such as storing data and/or instructions to facilitate the operation of the wireless communication device 220 and/or to provide storage of user information.

The power management system 325 provides a number of power management functions of the wireless communication device 320. In certain implementations, the power management system 325 includes a PA supply control circuit that controls the supply voltages of the power amplifiers 331. For example, the power management system 325 can be configured to change the supply voltage(s) provided to one or more of the power amplifiers 331 to improve efficiency, such as power added efficiency (PAE).

As shown in FIG. 17, the power management system 325 receives a battery voltage from the battery 328. The battery 328 can be any suitable battery for use in the wireless communication device 320, including, for example, a lithium-ion battery.

### Terminology and Conclusion

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes example embodiments, the teachings described herein can be applied to a variety of structures. Any of the principles and advantages discussed herein can be implemented in association with RF circuits configured to process signals having a frequency in a range from about 30 kHz to 300 GHz, such as in a frequency range from about 400 MHz to 8.5 GHz, in FR1, in a frequency range from about 2 GHz to 10 GHz, in a frequency range from about 2 GHz to 15 GHz, or in a frequency range from 5 GHz to 20 GHz.

Aspects of this disclosure can be implemented in various electronic devices. Examples of the electronic devices can include, but are not limited to, consumer electronic products, parts of the consumer electronic products such as packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an car piece, a telephone, a television, a computer monitor, a computer, a modem, a hand-held computer, a laptop computer, a tablet computer, a microwave, a refrigerator, a vehicular electronics system such as an automotive electronics system, a robot such as an industrial robot, an Internet of things device, a stereo system, a digital music player, a radio, a camera such as a digital camera, a portable memory chip, a home appliance such as a washer or a dryer, a peripheral device, a wrist watch, a clock, etc. Further, the electronic devices can include unfinished products.

Unless the context indicates otherwise, throughout the description and the claims, the words “comprise,” “comprising,” “include,” “including” and the like are to generally be construed in an inclusive sense, as opposed to an exclusive or exhaustive sense; that is to say, in the sense of “including, but not limited to.” Conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively.

While certain embodiments have been described, these embodiments have been presented by way of example only, and are not intended to limit the scope of the disclosure. Indeed, the novel resonators, filters, multiplexer, devices, modules, wireless communication devices, apparatus, methods, and systems described herein may be embodied in a variety of other forms. Furthermore, various omissions, substitutions, and changes in the form of the resonators, filters, multiplexer, devices, modules, wireless communication devices, apparatus, methods, and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and/or acts of the various embodiments described above can be combined to provide further embodiments. The accompanying claims and their equivalents are intended to cover such forms or modifications as would fall within the scope and spirit of the disclosure.

What is claimed is:

1. A bulk acoustic wave device having a main acoustically active region and a frame region, the bulk acoustic wave device comprising:
a first electrode;
a second electrode spaced apart from the first electrode in a first direction;
a frame structure in the frame region;
a piezoelectric layer positioned between the first electrode and the second electrode in at least the main acoustically active region; and
a dielectric layer in at least part of the frame region such that the piezoelectric layer is positioned between portions of the dielectric layer in a second direction different from the first direction, the dielectric layer including a different material than the piezoelectric layer.

2. The bulk acoustic wave device of claim 1 wherein the frame region surrounds the main acoustically active region.

3. The bulk acoustic wave device of claim 1 wherein the dielectric layer spans the frame region.

4. The bulk acoustic wave device of claim 1 further comprising an air cavity, the dielectric layer being over the air cavity in the at least part of the frame region.

5. The bulk acoustic wave device of claim 1 wherein the dielectric layer includes an oxide.

6. The bulk acoustic wave device of claim 1 wherein the dielectric layer includes a nitride.

7. The bulk acoustic wave device of claim 1 wherein the dielectric layer includes a carbide.

8. The bulk acoustic wave device of claim 1 wherein the dielectric layer includes at least one of silicon oxide, silicon nitride, silicon carbide, gallium oxide, or gallium nitride.

9. The bulk acoustic wave device of claim 1 wherein the dielectric layer includes a material that has an acoustic impedance with a magnitude that is at least 10% greater than a magnitude of an acoustic impedance of the piezoelectric layer.

10. The bulk acoustic wave device of claim 1 wherein the dielectric layer includes a material that has an acoustic impedance with a magnitude that is less than a magnitude of an acoustic impedance of the piezoelectric layer.

11. The bulk acoustic wave device of claim 1 wherein the dielectric layer has a higher thermal conductivity than the piezoelectric layer.

12. The bulk acoustic wave device of claim 1 wherein a piezoelectric coupling coefficient (e₃₃) of the dielectric layer has a magnitude that is no more than 50% of a magnitude of an e₃₃ of the piezoelectric layer.

13. The bulk acoustic wave device of claim 1 wherein a piezoelectric coupling coefficient (e₃₃) of the dielectric layer has a magnitude that is no more than 20% of a magnitude of an e₃₃ of the piezoelectric layer.

14. The bulk acoustic wave device of claim 1 wherein the dielectric layer is included in an intermediate region of the bulk acoustic wave device that is between the frame region and the main acoustically active region.

15. The bulk acoustic wave device of claim 1 wherein the dielectric layer is included in an outer region of the bulk acoustic wave device that is on an opposite side of the frame region than the main acoustically active region.

16. The bulk acoustic wave device of claim 1 wherein the frame structure includes a raised frame structure and a recessed frame structure.

17. The bulk acoustic wave device of claim 1 wherein the frame region includes a first raised frame region and a second raised frame region, and the frame structure includes an additional raised frame layer in the second raised frame region relative to in the first raised frame region.

18. The bulk acoustic wave device of claim 1 wherein the frame structure includes a recessed frame structure.

19. An acoustic wave filter for filtering a radio frequency signal, the acoustic wave filter comprising:
a bulk acoustic wave resonator including a first electrode, a second electrode spaced apart from the first electrode in a first direction, a frame structure in a frame region, a piezoelectric layer positioned between the first electrode and the second electrode in at least a main acoustically active region, and a dielectric layer in at least part of the frame region such that the piezoelectric layer is positioned between portions of the dielectric layer in a second direction different from the first direction, the dielectric layer including a different material than the piezoelectric layer; and
a plurality of additional acoustic wave resonators, the bulk acoustic wave resonator and the plurality of additional acoustic wave resonators configured to filter the radio frequency signal.

20. A radio frequency module comprising:
a filter including a bulk acoustic wave resonator including a first electrode, a second electrode spaced apart from the first electrode in a first direction, a frame structure in a frame region, a piezoelectric layer positioned between the first electrode and the second electrode in at least a main acoustically active region, and a dielectric layer in at least part of the frame region such that the piezoelectric layer is positioned between portions of the dielectric layer in a second direction different from the first direction, the dielectric layer including a different material than the piezoelectric layer;
radio frequency circuitry; and
a package structure enclosing the filter and the radio frequency circuitry.
